(19) United States
(12) Patent Application Publication
(10) Pub. No.: US 2012/0149145 A1
(43) Pub. Date: Jun. 14, 2012

(54) METHOD FOR MANUFACTURING IMAGE SENSOR

(75) Inventors: Kuo-Yuh YANG, Zhubei City (TW); Chia-Huei Lin, Hsinchu City (TW)

(73) Assignee: UNITED MICROELECTRONICS CORP., Hsinchu (TW)

(21) Appl. No.: 12/965,098

(22) Filed: Dec. 10, 2010

(51) Int. Cl. H01L 31/18

(52) U.S. Cl. 438/87; 257/E31.032

(57) ABSTRACT

A method for manufacturing an image sensor, wherein the method comprises several steps as follows: A semiconductor base doped with dopants having a first-type electrical conductivity is provided, wherein the semiconductor base comprises a handle wafer, an oxide insulator disposed on the handle wafer, and a silicon layer disposed on the oxide insulator. A front end process is then conducted, to form at least one imaging pixel disposed in the silicon layer and at least one metal layer disposed on the imaging pixel, whereby the first-type electrical dopants can be driven into the silicon layer to form a doping layer with the first-type electrical conductivity over the oxide insulator.

### FIELD OF THE INVENTION

The present invention relates to a method for fabricating a semiconductor device, more particularly to a method for manufacturing a metal-oxide semiconductor field effect transistor (MOSFET).

### BACKGROUND OF THE INVENTION

FIGS. 1A to 1B illustrate a typical process for manufacturing an image sensor 10 in accordance with prior art. Referring to FIG. 1A, at least one imaging pixel 100 isolated by a plurality of insulating regions 103 is first formed on a semiconductor substrate 102 (such as a bulk wafer). The imaging pixel 100 comprises a photodiode 104 which includes an N type (or P type) diffusion region 104a and a P type (or N type) pinning layer 104b disposed above the diffusion region 104a, an N type (or P type) floating diffusion region 101 separated from the photodiode 104; and a transfer gate 108 in contact with the diffusion region 104a, the pinning layer 104b and the floating diffusion region 101.

Subsequently, a front-end process is conducted to form a plurality of metal layers 112 having several stacked metal lines 112a buried in inter-layer dielectric layers 112b over the substrate 102, the photodiode 104 and the transfer gate 108.

After the front-end process is conducted, a working wafer (not shown) is bonded on the metal layer 112 and a thinning process is conducted to remove a portion of the semiconductor substrate 102, and an ion implantation process 114 is than conducted from the backside of the substrate 102 (as shown in FIG. 1A) to implant boron (or phosphorous) ions into the substrate 102 to form a doping layer 118 (as shown in FIG. 1B). Subsequently, a laser annealing process 116 is conducted on the substrate 102 to activate the doping layer 118.

However, the elements constructed in the front-end process, such as the transfer gate 108 and the metal layers 112, may be damaged or affected by the ion implantation process 114 and the laser annealing process 116 due to high operational temperature.

Therefore it is necessary to provide an improved method for manufacturing an image sensor that can improve production process and yield on one hand, and can reduce the fabricating cost on the other hand.

### SUMMARY OF THE INVENTION

One aspect of the present invention is to provide a method for manufacturing an image sensor, wherein the method comprises several steps as follows: A semiconductor base doped with dopants having a first-type electrical conductivity is provided, wherein the semiconductor base comprises a handle wafer, an oxide insulator disposed on the handle wafer, and a silicon layer disposed on the oxide insulator. A front-end process is then conducted, to form at least one imaging pixel disposed in the silicon layer and at least one metal layer disposed on the imaging pixel, whereby the first-type electrical dopants can be driven into the silicon layer to form a doping layer with the first-type electrical conductivity over the oxide insulator.

In some embodiments of the present invention, the handle wafer of the semiconductor base is doped with the first-type electrical dopants; in other embodiments of the present invention the first-type electrical dopants are otherwise doped in the oxide insulator of the semiconductor base.

In some embodiments of the present invention, the front-end process comprises at least one thermal step for driving the first-type electrical dopants into the silicon layer to form the doping layer, wherein the thermal step has an processing temperature substantially ranged from 800° C. to 1200° C. In another embodiment of the present invention, the front-end process comprises at least one ion implantation process for driving the he first-type electrical dopants into the silicon layer to form the imaging pixel. In some embodiments of the present invention, further comprises at least one thermal step after the front-end process is completed for driving the first-type electrical dopants to diffuse deep into the silicon layer to form the doping layer. And in some embodiments of the present invention, the doping layer has a dopant concentration substantially ranges from 10¹⁶/cm³ to 10¹⁹/cm³.

In the present invention, the imaging pixel comprises a photodiode and a floating diffusion region disposed in the silicon layer, and a transfer gate in contact with the photodiode and the floating diffusion region, wherein the photodiode includes a diffusion region having a second-type electrical and a pinning layer having the first-type electrical conductivity disposed on the second-type electrical diffusion region. In some embodiments of the present invention, the first-type electrical conductivity is P type electrical conductivity, and the second-type electrical conductivity is N type electrical conductivity. Rather in some other embodiments of the present invention, the first-type electrical conductivity is N type electrical conductivity, and the second-type electrical conductivity is P type electrical conductivity.

In some embodiment of the present invention, after the doping layer is formed a working wafer is bonded on the metal layer and a thinning process is conducted to remove the handle wafer and a portion of the oxide insulator, wherein the thinning process is a wafer grinding process or a chemical mechanical polishing (CMP) process.

In some embodiments of the present invention, the image sensor is a backside illuminated image sensor. However, in other embodiments of the present invention, the image sensor is a front side illuminated image sensor.

Another aspect of the present invention is to provide a method for manufacturing an image sensor, wherein the method comprises several steps as follows: A semiconductor base having a handle wafer, an oxide insulator disposed on the handle wafer, and a silicon layer disposed on the oxide insulator is provided. A front-end process is then conducted to form at least one imaging pixel disposed in the substrate. Subsequently, a deep ion implantation is conducted on the imaging pixel to drive a plurality of dopants having a first-type electrical conductivity implanting into the silicon layer, so as to form a doping layer with the first-type electrical conductivity over the oxide insulator. Thereafter, at least one metal layer is formed on the imaging pixel.

In some embodiments of the present invention, the implantation depth of the deep ion implantation is substantially ranged from 1.5 μm to 4 μm, the doping layer has a dopant concentration substantially ranges from 10¹⁶/cm³ to 10¹⁹/cm³.

In the present invention, the imaging pixel comprises a photodiode and a floating diffusion region disposed in the silicon layer, and a transfer gate in contact with the photodiode and a floating diffusion region, wherein the photodiode includes a diffusion region having a second-type electrical and a pinning layer having the first-type electrical conductivity disposed on the second-type electrical diffusion region, and the doping layer is formed between the second-type electrical diffusion region and the oxide insulator.

In some embodiments of the present invention, the first-type electrical conductivity is P type electrical conductivity, and the second-type electrical is an N type electrical conductivity. Rather in some other embodiments of the present invention, the first-type electrical conductivity is N type electrical conductivity, and the second-type electrical conductivity is P type electrical conductivity.

In some embodiment of the present invention, after the doping layer is formed a working wafer is bonded on the metal layer and a thinning process is conducted to remove the handle wafer and a portion of the oxide insulator, wherein the thinning process is a wafer grinding process or a CMP process.

In some embodiments of the present invention, the image sensor is a backside illuminated image sensor. However, in other embodiments of the present invention, the image sensor is a front side illuminated image sensor.

According to aforementioned embodiments of the present invention, a semiconductor base having a handle wafer, an oxide insulator and a silicon layer is adopted as a starting substrate to form an image sensor. In one aspect of the present invention, the semiconductor base is adopted doped with dopants having an predetermined electrical conductivity is applied to form the image sensor, wherein the intrinsic thermal energy of a front-end process for forming some essential elements can be used to drive the dopants diffusing into the silicon layer to form an essential doping layer without conducting any additional ion implantation or laser annealing process.

In accordance with another aspect of the present invention, the semiconductor base is subjected to an ion implantation process prior to a similar front-end process to drive dopants having a predetermined electrical conductivity implanting into the silicon layer to form a doping layer, wherein the diffusion depth of the dopants can be manipulated precisely in associated with the parameters of the front-end process without requiring any subsequent laser annealing process.

Thus by adopting these present approaches, the fabricating cost should be significantly reduced in comparison with the conventional approaches, and the problems due to the high operation temperature of the laser annealing can also be solved.

In order to make the aforementioned and other objects, features and advantages of the present invention comprehensible, preferred embodiments accompanied with figures are described in detail below.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1B are cross sections of a semiconductor structure illustrating a process for manufacturing an image sensor in accordance with prior art.

FIGS. 2A to 2C are cross sections illustrating a process for manufacturing an image sensor in accordance with an embodiment of the present invention.

FIGS. 3A to 3C are cross sections illustrating a process for manufacturing an image sensor in accordance with another embodiment of the present invention.

FIGS. 4A to 4E are cross sections illustrating a process for manufacturing an image sensor in accordance with a further embodiment of the present invention.

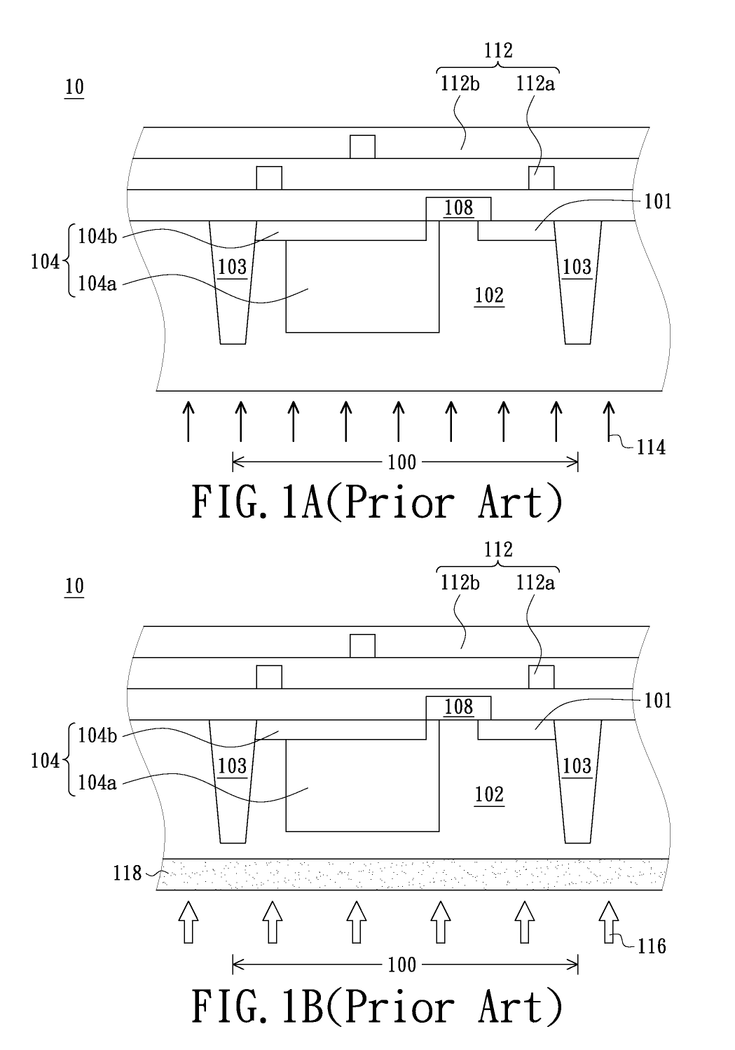

### DETAILED DESCRIPTION OF PREFERRED EMBODIMENTS

Detail descriptions of several embodiments eligible to exemplify the features of making and using the present invention are disclosed as follows. It must be appreciated that the following embodiments are just exemplary, but not used to limit the scope of the present invention. Wherever possible, the same reference numbers are used in the drawings and the description to refer to the same or like parts.

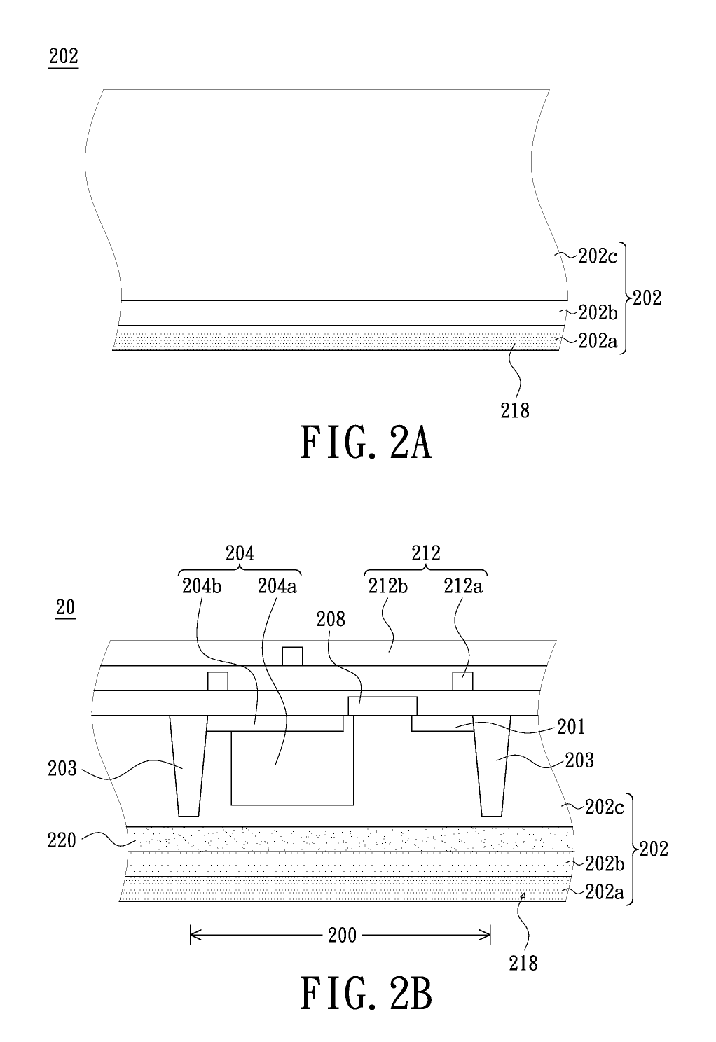

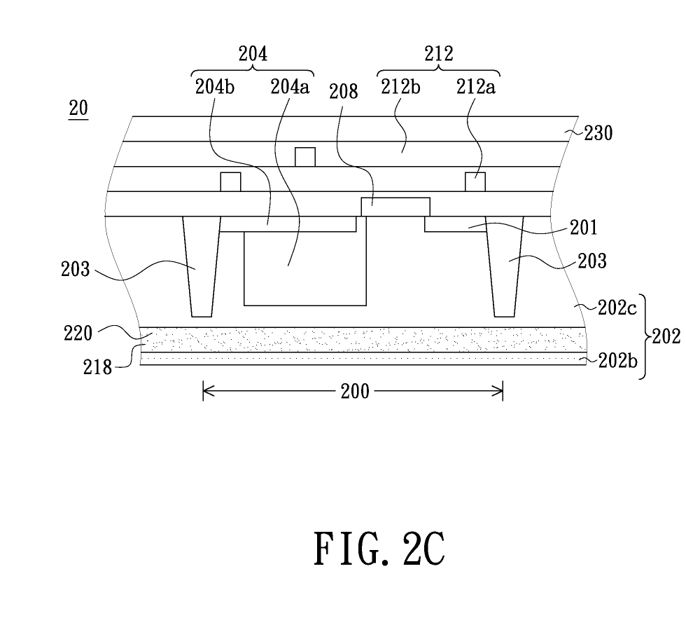

FIGS. 2A to 2C illustrate a process for manufacturing a backside illuminated image sensor 20 in accordance with an embodiment of the present invention. Referring to FIG. 2A, a semiconductor base 202 doped with dopants having a first-type electrical conductivity is provided, wherein the semiconductor base 202 comprises a handle wafer 202a, an oxide insulator 202b disposed on the handle wafer 202a, and a silicon layer 202c disposed on the oxide insulator 202b. In the present embodiment, the handle wafer 202a is doped with the P type (or N type) dopants 218, such as boron (or phosphorous) ions; the oxide insulator 202b is preferably a silicon oxide layer; and the silicon layer 202c is preferably an epitaxial silicon layer grown on the oxide insulator 202b.

Subsequently, a front-end process is conducted on the front side of the silicon layer 202c to form at least one imaging pixel 300 with the silicon layer 202c and at least one stacked metal layer 212 disposed on the imaging pixel 300.

The at least one imaging pixel 300 comprises a photodiode 3204, a floating diffusion region 201 and a transfer gate 308. Preferably but not necessarily, the photodiode 3204 has an N type (or P type) diffusion region 3204a and a P type (or N type) pinning layer 3204b disposed on the N type (or P type) diffusion region 3204a; the floating diffusion region 201 is disposed in the silicon layer 202c and separated from the photodiode 3204; and the transfer gate 308 is disposed on the photodiode 3204 and floating diffusion region 201 in contact with the N type (or P type) diffusion region 3204a, the P type (or N type) pinning layer 3204b and the floating diffusion region 201. The at least one stacked metal layer 212 comprises at least one metal line 212a buried in at least one inter-layer dielectric layer 212b.

It is understood by the persons skilled in the art that the front-end process inherently involves one or more thermal steps and one or more ion implantation process conducted under a temperature high enough for driving the P type (or N type) dopants 218 into the silicon layer 202c to form a P type (or N type) doping layer 220 between the oxide insulator 202b and the N type (or P type) diffusion region 3204a, but not damaging the device. For example, the front-end process may comprise a thermal oxidation step for forming a plurality of insulating regions 201 in the silicon layer 202c to define the image pixel 300, with a processing temperature substantially ranged from 800° C. to 1200° C., whereby the P type (or N type) dopants 218 can be driven to diffuse from the handle wafer 202a via the oxide insulator 202b into the silicon layer 202c by the intrinsic thermal energy of the thermal step, so as to form the P type (or N type) doping layer 220 in the silicon layer 202c. In another example, the thermal step may be the step for forming spacers (not shown) of the transfer gate 308. Moreover, during the lightly doped drain (LDD) implant process and other implantation steps for forming, for example, the floating diffusion region 201 and the N type (or P type) diffusion region 3204a, the processing temperature is commonly ranged from 800 to 1200. As the consequence of the thermal or ion implantation steps, the P type (or N type) doping layer 220 may have a dopant concentration substantially ranges from 10¹⁶/cm³ to 10¹⁹/cm³ and the dopant concentration preferably is greater than 10¹⁸/cm³.

After the doping layer 220 is formed, a working wafer 230 is bonded on the metal layer 212 and a thinning process, such as a wafer grinding or a chemical mechanical polishing (CMP) process, is then conducted to remove the handle wafer 202a and a portion of the oxide insulator 202b. However, in some embodiments of the present invention, the thinning process may thoroughly remove the handle wafer 202a and the oxide insulator 202b to expose the backside of the silicon layer 202c, and another thin silicon oxide layer (not shown) may be formed to blank the backside of the silicon layer 202c. After the thinning process, further steps may be subsequently conducted to accomplish the backside illuminated image sensor 20.

If necessary, after the front-end process is conducted, an additional thermal process could be applied to further drive the P type (or N type) dopants 218 into the silicon layer 202c. Besides, the original thickness of the SOI 202, including the original thickness of the handle wafer 202a, the oxide insulator 202b and the silicon layer 202c, can be manipulated in associated with the parameters of the front-end process to satisfy the depth or thickness requirement of the doping layer 220. Therefore, the diffusion depth of the P type (or N type) dopants 218 may be controlled more precisely, thus the production yield of the backside illuminated image sensor 30 may be significantly improved.

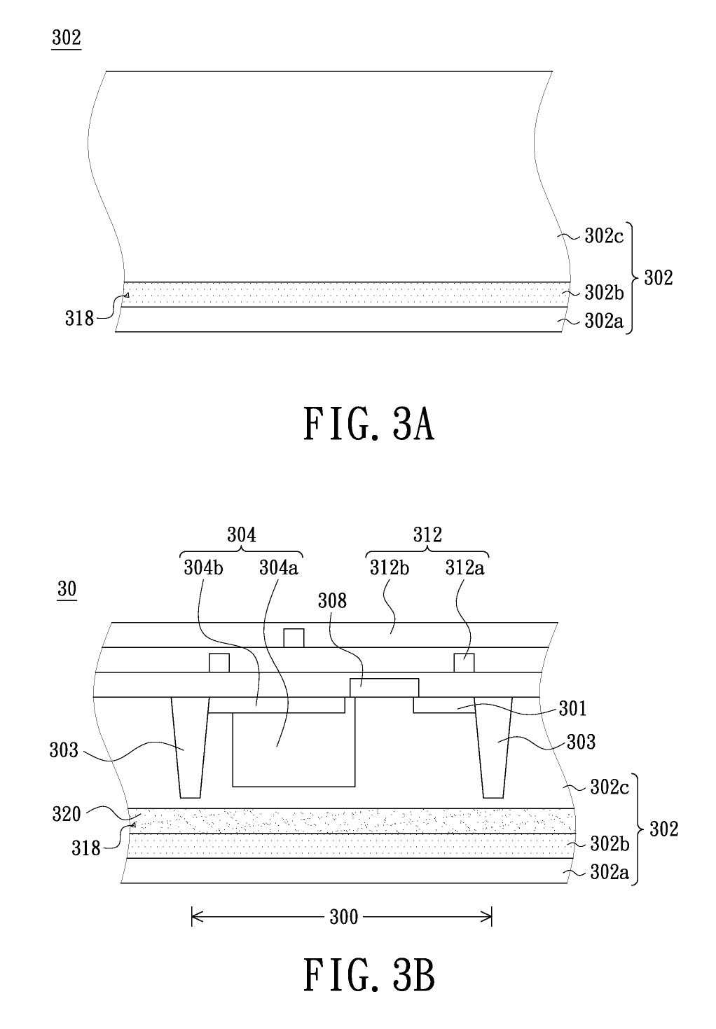

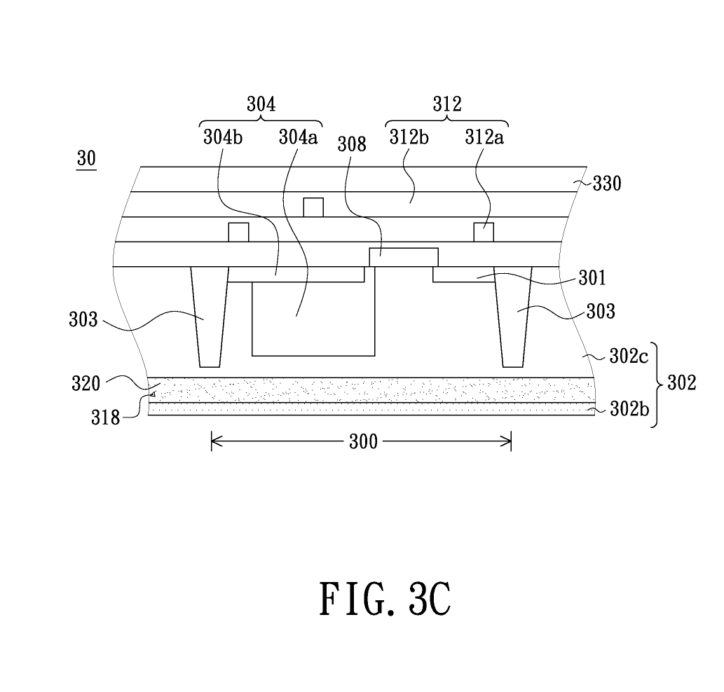

FIGS. 3A to 3C illustrate a process for manufacturing a backside illuminated image sensor 30 in accordance with another embodiment of the present invention. Referring to FIG. 3A, a semiconductor base 302 doped with dopants having a first-type electrical conductivity is provided, wherein the semiconductor base 302 comprises a handle wafer 302a, an oxide insulator 302b disposed on the handle wafer 302a, and a silicon layer 302c disposed on the oxide insulator 302b. In the present embodiment, the oxide insulator 302b is preferably a silicon oxide layer doped with P type (or N type) dopants 318, such as boron (or phosphorous) ions; and the silicon layer 302c is preferably an epitaxial silicon layer grown on the oxide insulator 302b.

Subsequently, a front-end process is then conducted on the front side of the silicon layer 302c, to form at least one imaging pixel 300 with the silicon layer 302c, and at least one stacked metal layer 312 disposed on the imaging pixel 300. The at least one imaging pixel 300 comprises a photodiode 304, a floating diffusion region 301 and a transfer gate 308. Preferably but not necessarily, the photodiode 304 has N type (or P type) diffusion region 304a and a P type (or N type) pinning layer 304b disposed on the N type (or P type) diffusion region 304a; the floating diffusion region 301 is disposed in the silicon layer 302c and separated from the photodiode 304; and the transfer gate 308 is disposed on the photodiode 304 and the floating diffusion region 301 in contact with the N type (or P type) diffusion region 304a, the P type (or N type) pinning layer 304b and the floating diffusion region 301. The at least one stacked metal layer 312 comprises at least one metal line 312a buried in least one inter layer dielectric layer 312b.

It is understood by the persons skilled in the art that the front end process inherently involves one or more thermal steps and one or more ion implantation process conducted under a temperature high enough for driving the P type (or N type) dopants 318 into the silicon layer 302c to form a P type (or N type) doping layer 320 between the oxide insulator 302b and the N type (or P type) diffusion region 304a, but not damaging the device. For example, the front-end process may comprise a thermal oxidation step for forming a plurality of insulating region 301 in the silicon layer 302c to define the image pixel 300, with a processing temperature substantially ranged from 800° C. to 1200° C., whereby the P type (or N type) dopants 318 can be driven to diffuse from the oxide insulator 302b into the silicon layer 302c by the intrinsic thermal energy of the thermal steps, so as to form the P type (or N type) doping layer 320 in the silicon layer 302c. In some another example, the thermal step may be the step for forming spacers (not shown) of the transfer gate 308. Moreover, during the LDD implant process and other implantation step steps for forming, for example, the floating diffusion region 301 and the N type (or P type) diffusion region 304a, the processing temperature is commonly ranged from 800° C. to 1200° C. As the consequence of the thermal or ion implantation steps, the P type (or N type) doping layer 320 may have a dopant concentration substantially ranges from 10¹⁶/cm³ to 10¹⁹/cm³ and the dopant concentration preferably is greater than 10¹⁸/cm³.

After the doping layer 320 is formed, a working wafer 330 is bonded on the metal layer 312 and a thinning process , such as a wafer grinding or a CMP process is then conducted to remove the handle wafer 302a and a portion of the oxide insulator 302b. In some other embodiments of the present invention, however, the thinning process may thoroughly remove the handle wafer 302a and the oxide insulator 302b to expose the backside of the silicon layer 302c, and an another thin silicon oxide layer (not shown) may be formed to blank the backside of the silicon layer 302c. After the thinning process, further steps may be subsequently conducted to accomplish the backside illuminated image sensor 30.

If necessary, after the front-end process is conducted, an additional thermal process could be applied to drive the P type (or N type) dopants 318 further diffusing into the silicon layer 302c. Besides, the original thickness of the semiconductor base 302, including the original thickness of the handle wafer 302a, the oxide insulator 302b and the silicon layer 302c, can be manipulated in associated with the parameters of the front-end process to satisfy the depth or thickness requirement of the doping layer 320. Therefore, the diffusion depth of the P type (or N type) dopants 318 may be controlled more precisely, thus the production yields of the backside illuminated image sensor 30 may be significantly improved.

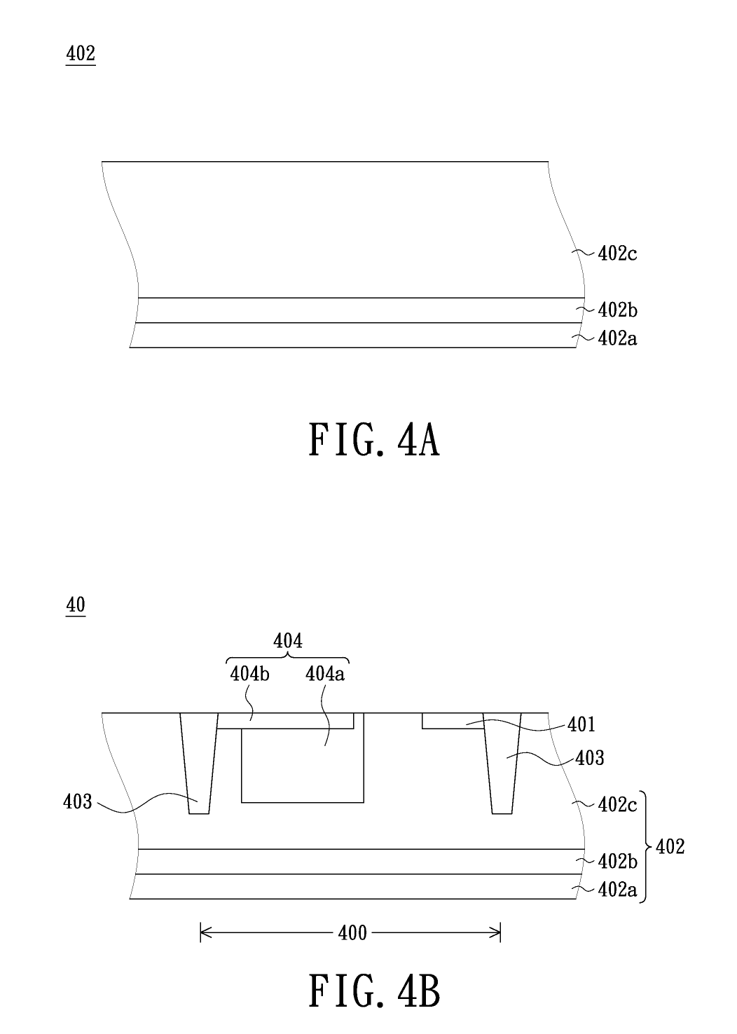

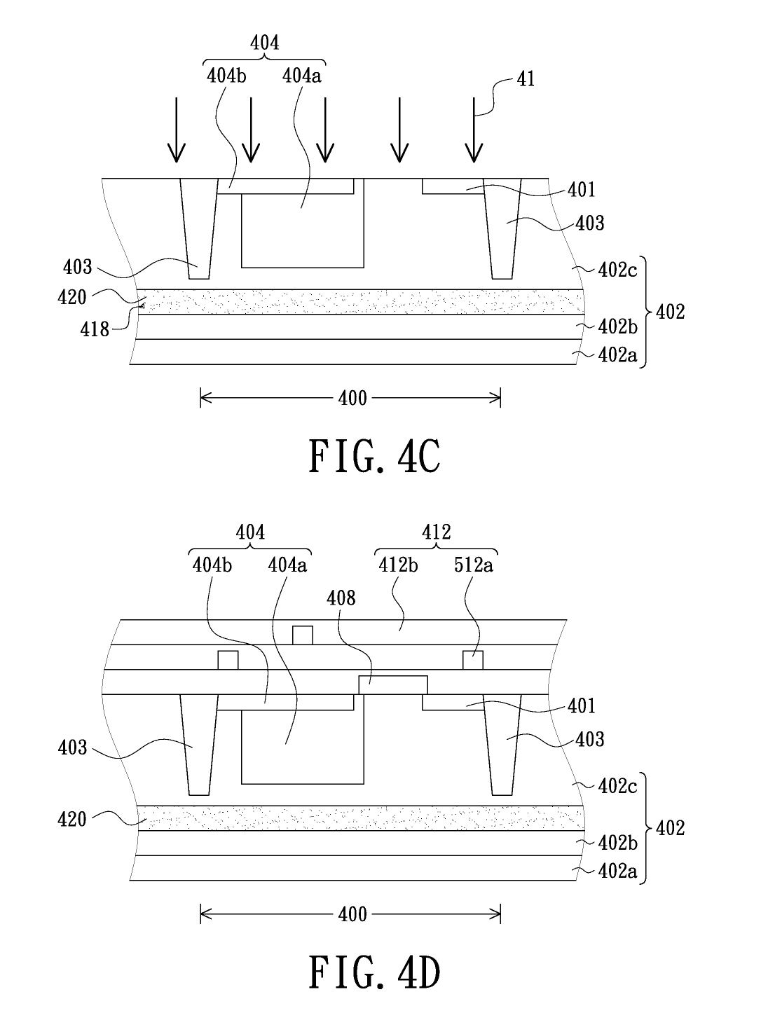

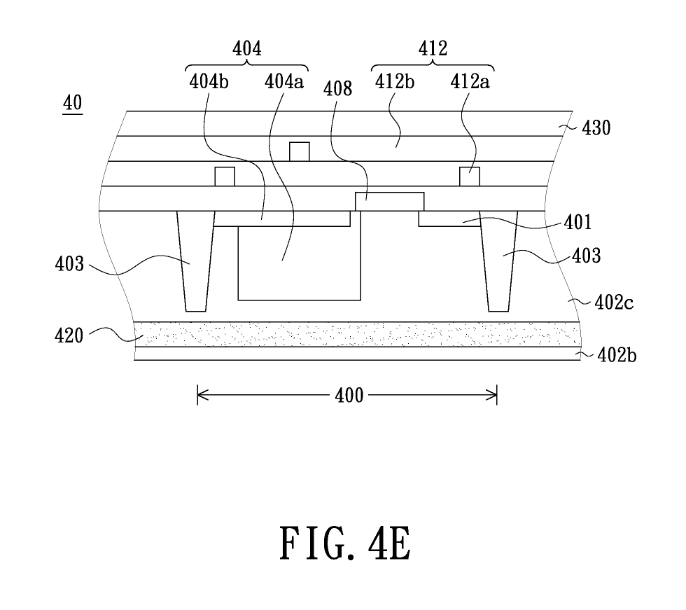

FIGS. 4A to 4E illustrate cross sections of the process for manufacturing a backside illuminated image sensor 4040 in accordance with another embodiment of the present invention. Referring to FIG. 4A, a semiconductor base 402 is provided, wherein the semiconductor base 402 comprises a handle wafer 402a, an oxide insulator 402b disposed on the handle wafer 402a, and a silicon layer 402c disposed on the oxide insulator 402b. In the present embodiment, the oxide insulator 402b is preferably a silicon oxide layer; and the silicon layer 402c is preferably an epitaxial silicon layer grown on the oxide insulator 402b.

Subsequently, a front-end process is then conducted on the front side of the silicon layer 402c to form at least one imaging pixel 400 with the silicon layer 402c (as shown in FIG. 4B The at least one imaging pixel 400 comprises a photodiode 404 which has an N type (or P type) diffusion region 404a and a P type (or N type) pinning layer 404b disposed above the diffusion region 404a, a floating diffusion region 401 separated from the photodiode 404 and a transfer gate 408. Preferably but not necessarily, the photodiode 404, wherein the P type (or N type) pinning layer 404b is disposed on the N type (or P type) diffusion region 404a; the floating diffusion region 401 is disposed in the silicon layer 402c separated from the photodiode 404, and the transfer gate 408 is disposed on the photodiode 404 and the floating diffusion region 401 in contact with the N type (or P type) diffusion region 404a, the P type (or N type) pinning layer 404b and the floating diffusion region 401.

A deep ion implantation 41 is then conducted on the imaging pixel 400 to drive a plurality of P type (or N type) dopants 418 implanting into the silicon layer 402c, so as to form a P type (or N type) doping layer 420 between the N type (or P type) diffusion region 404a and the oxide insulator 402b (as shown in FIG. 4C). In some embodiments of the present invention, the processing temperature of the deep ion implantation 41 is commonly ranged from 800 to 1100° C. As the consequence of the deep ion implantation steps the implantation depth can be controlled in a range substantially from 1.5 μm to 4 μm; and the doping layer 420 has a dopant concentration substantially ranges from 10¹⁶/cm³ to 10¹⁹/cm³ and the dopant concentration preferably is greater than 10¹⁸/cm³. The parameters of the deep ion implantation 41 can be manipulated to satisfy the depth or thickness requirement of the doping layer 420. Therefore, the diffusion depth of the P type (or N type) dopants 418 may be controlled more precisely, thus the production yields of the backside illuminated image sensor 40 may be significantly improved.

Of note that in the present embodiment the transfer gate 408 is formed during the front-end process; but in another embodiment, the transfer gate 408 may be formed after the deep ion implantation 41 is completed.

Thereafter, at least one staked metal layer 412 is formed on the imaging pixel 400, as shown in FIG. 4D, wherein stacked metal layer 412 comprises at least one metal line 412a buried in least one inter layer dielectric layer 412b. A working wafer 430 is bonded on the metal layer 412 and a thinning process , such as a wafer grinding or a CMP process is then conducted to remove the handle wafer 402a and a portion of the oxide insulator 402b. After the thinning process, some further steps may be subsequently conducted to accomplish the backside illuminated image sensor 40 (as shown in FIG. 4E).

According to aforementioned embodiments of the present invention, a semiconductor base having a handle wafer, an oxide insulator and a silicon layer is adopted as a starting substrate to form an image sensor. In one aspect of the present invention, the semiconductor base is adopted doped with dopants having an predetermined electrical conductivity is applied to form the image sensor, wherein the intrinsic thermal energy of a front-end process for forming some essential elements can be used to drive the dopants diffusing into the silicon layer to form an essential doping layer without conducting any additional ion implantation or laser annealing process.

In accordance with another aspect of the present invention, the semiconductor base is subjected to an ion implantation process prior to a similar front-end process to drive dopants having a predetermined electrical conductivity implanting into the silicon layer to form a doping layer, wherein the diffusion depth of the dopants can be manipulated precisely in associated with the parameters of the front-end process without requiring any subsequent laser annealing process.

Furthermore, in comparison with the prior arts, the diffusion depth of the implantation dopants can be controlled more precisely, and the production yield of the backside illuminated image sensor can be improved significantly. Therefore the fabricating cost can be significantly reduced, and the problems due to the high operation temperature of the laser annealing can also be solved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A method for manufacturing an image sensor, the method comprising:
providing a semiconductor base comprises a handle wafer doped with dopants having a first-type electrical conductivity, an oxide insulator disposed on the handle wafer, and a silicon layer disposed on the oxide insulator; and
conducting a front end process to form at least one imaging pixel with the silicon layer and at least one metal layer above the imaging pixel, whereby the first-type electrical dopants initially doped in the handle wafer of the semiconductor base can be diffused into the silicon layer to form a doping layer having the first-type electrical conductivity.

2. (canceled)

3. The method of claim 1, wherein the first-type electrical dopants are doped in the oxide insulator of the semiconductor base.

4. The method of claim 1 for manufacturing the image sensor, wherein the front end process comprises at least one thermal step for driving the first-type electrical dopants into the silicon layer to form the doping layer.

5. The method of claim 4 for manufacturing the image sensor, wherein the thermal step has an processing temperature substantially ranged from 800° C. to 1200° C.

6. The method of claim 1 for manufacturing the image sensor, wherein the front end process comprises at least one ion implantation process on the silicon layer to form the imaging pixel.

7. The method of claim 1 for manufacturing the image sensor, wherein the doping layer has a dopant concentration substantially ranging from 10¹⁶/cm3 to 10¹⁹/cm3.

8. The method of claim 1 for manufacturing the image sensor, further comprising at least one thermal step conducted after the front end process, for further driving the first-type electrical dopants to diffuse into the silicon layer.

9. The method of claim 1 for manufacturing the image sensor, wherein the imaging pixel comprises a photodiode and a floating diffusion region disposed in the silicon layer, and a transfer gate in contact with the photodiode and the floating diffusion region.

10. The method of claim 9 for manufacturing the image sensor, wherein the photodiode includes a diffusion region having a second-type electrical conductivity and a pinning layer having the first-type electrical conductivity disposed on the second-type electrical diffusion region.

11. The method of claim 10 for manufacturing the image sensor, wherein the first-type electrical conductivity is P type electrical conductivity and the second-type electrical conductivity is N type electrical conductivity.

12. The method of claim 10 for manufacturing the image sensor, wherein the first-type electrical conductivity is N type electrical conductivity and the second-type electrical conductivity is P type electrical conductivity.

13. The method of claim 1 for manufacturing the image sensor, further comprising a bonding a working wafer on the metal layer and conducting a thinning process to remove the handle wafer and a portion of the oxide insulator after the doping layer is formed, wherein the thinning process is a wafer grinding process or a chemical mechanical polishing (CMP) process.

14-20. (canceled)
